(19) United States
(12) Patent Application Publication
(10) Pub. No.: US 2006/0281014 A1
(43) Pub. Date: Dec. 14, 2006

(54) Method and apparatus for protecting a reticle used in chip production from contamination

(75) Inventors: Marinus Antonius Dimphna Maria Loos, Eindhoven (NL); Rudolf Maria Jozef Voncken, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: koninklijke phillips electronics n.v.

(21) Appl. No.: 10/572,842

(22) PCT Filed: Sep. 15, 2004
(86) PCT No.: PCT/IB04/51772

§ 371 Date: Mar. 21, 2006

(30) Foreign Application Priority Data
Sep. 23, 2003 (EP) 03103508.2

(51) Int. Cl. A47G 1/12; G03C 5/00; G03F 1/14; G03F 1/00

(52) U.S. Cl. 430/5; 428/14; 430/311; 430/312; 430/313

(57) ABSTRACT

A transparent pellicle member (1), comprising an inner or central portion (1A) and an out peripheral portion (1B) mounted across a reticle for use in semiconductor chip fabrication, substantially parallel thereto and with a space (9) therebetween. The central portion (1A) of the pellicle (1) is fixed with regard to position and tilt angle to the reticle base plate (5) by means of one or more anchors (50). The outer or peripheral portion (1B) of the pellicle (1) is separate from the central portion (IA). It is connected on each side to the central portion (1A) and to a frame (3) by means of flexible connectors (30), which are sufficiently flexible to permit movement of the peripheral portion (1B) of the pellicle membrane in a direction perpendicular to the reticle, but is sufficiently resistant to movement thereof in other directions. As a result, the gas pressure difference between the space (9) and the surrounding atmosphere supports the outer portion (1B) of the pellicle (1) using the weight of that portion of the pellicle (1) itself. As a result of the “floating” portion (113), a pressure difference is created which is required to avoid deflection of the inner portion (1A).

This invention relates to a method and apparatus for protecting a reticle used in chip production from contamination and, more particularly, to a pellicle and a method of mounting such a pellicle relative to a reticle.

Patterned lithographic masks are utilised in semiconductor chip fabrication, and such lithographic masks need to be protected from particle contamination since foreign matter on a mask will produce a printed defect in the electronic circuit being created on a silicon wafer.

For current lithographic manufacture of semiconductor chips, masks are enclosed in a “pellicle” (currently 1 micrometer polyamide) to protect them from particles. The mask consists of a rigid substrate with a patterned absorbing film on one surface. A pellicle is a thin membrane, stretched over a frame mounted to the mask substrate, which prevents particles from striking patterned areas of the mask. The pellicle is offset from the mask in an “out of focus” image plane, producing a gap between the mask surface (requiring protection) and the pellicle. This offset ensures that particles intercepted by the pellicle do not produce image defects.

For the photon wavelengths used in earlier chip manufacture techniques (365 nm, 248 nm), the pellicle is highly transparent and allows the lithographic radiation to be transmitted to the mask with high efficiency. Pellicles stay affixed to the mask mounting hardware throughout the life of the mask and allow the mask to be handled and inspected free from defect-producing particle contamination.

The next generation of lithographic techniques, including 157 nm optical projection lithography, utilise ionising radiation (photons, ions and electrons, respectively) to perform lithographic imaging. Thus, the masks used in these next generation lithographic techniques are irradiated with ionising radiation during the lithographic exposure. A traditional pellicle cannot be used next generation lithography because the pellicle would absorb too much of the ionising radiation. A membrane might also degrade in the ionising beam, eventually failing and allowing the mask to become contaminated.

We have now devised an improved arrangement.

In accordance with the present invention, there is provided apparatus for protecting a reticle used in semiconductor chip fabrication from contamination, the apparatus comprising a pellicle member disposed over said reticle with a gas-tight space therebetween by connection means, characterized in that said pellicle member comprises a central portion and an outer portion, said central and outer portions being separate from each other, said central portion having a fixed position and tilt angle, in use, and said connection means being configured to permit movement of said outer portion in a direction substantially perpendicular to said reticle in response to changes in gas pressure difference between said space and the atmosphere.

Also in accordance with the present invention, there is provided a method of protecting a reticle used in semiconductor chip fabrication from contamination, the method comprising the steps of providing a pellicle member and disposing it over said reticle with a gas-tight space therebetween by connection means, characterized in that said pellicle member comprises a central portion and an outer portion, said central and outer portions being separate from each other, said central portion having a fixed position and tilt angle, in use, and said connection means being configured to permit movement of said outer portion in a direction substantially perpendicular to said reticle in response to changes in gas pressure difference between said space and the atmosphere.

Still further in accordance with the present invention, there is provided a method of fabricating a semiconductor chip, comprising the steps of providing a reticle and apparatus for protecting said reticle from contamination as defined above, providing a patterned mask on said reticle, and irradiating said reticle through the central portion of the pellicle member and the mask.

Still further in accordance with the present invention, there is provided a semiconductor chip fabricated in accordance with the method defined above.

It will be appreciated that the space between the pellicle and the reticle is a closed volume filled with a gas, possibly but not necessarily, air.

The connection means may comprise flexible connection members, preferably arranged to extend and contract in response to the above-mentioned pressure differences so as to permit movement of the outer portion of the pellicle member in a direction perpendicular to the reticle.

In another embodiment, the connection members may comprise brackets slidably or otherwise connecting the outer portion of the pellicle member to a support frame, such that it can move in a direction substantially perpendicular to the reticle.

In yet another embodiment, the support frame may comprise longitudinal guides in which the edges of the outer portion of the pellicle member are arranged to be received in an gas-tight manner. Once again, the outer portion of the pellicle member is permitted to move up and down relative to the reticle by sliding up and down the gas-tight guides.

The inner portion of the pellicle member may be fixed with regard to its position and tilt angle by means of one or more anchor points, which may extend from selected positions on a reticle base plate or support frame, on which the reticle is supported or provided.

The pellicle member is preferably formed of silicon glass. The reticle is preferably provided on a reticle base plate, which base plate is preferably provided with a support frame to which the outer portion of the pellicle member is connected.

These and other aspects of the invention will be apparent from, and elucidated with reference to, the embodiment described herein.

An embodiment of the present invention will now be described by way of example only and with reference to the accompanying drawings, in which:

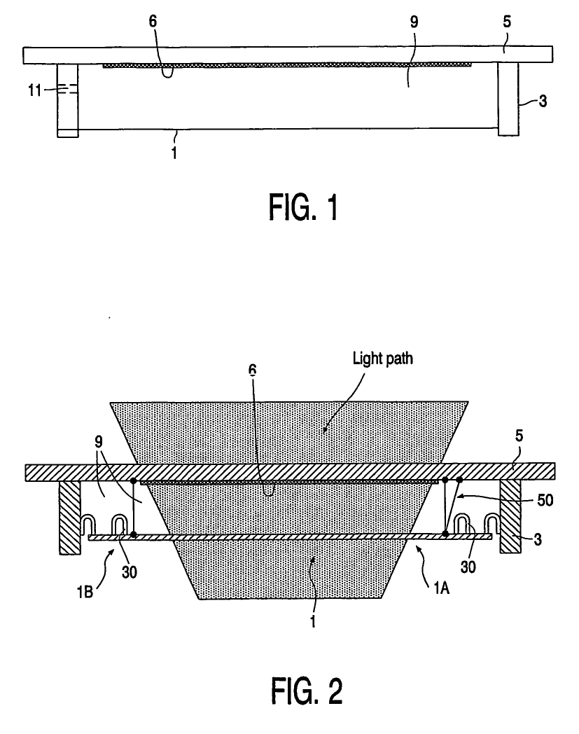

FIG. 1 is a schematic cross-sectional view of a conventional pellicle mounted on a reticle; and

FIG. 2 is a schematic cross-sectional view of an arrangement according to an exemplary embodiment of the present invention.

Referring to FIG. 1 of the drawings, a conventional arrangement comprises a thin pellicle member or plate 1 and a frame 3. The pellicle 1 is adhered to the frame 3, and a reticle base plate 5, carrying a reticle (i.e. a photolithographic surface) on one side thereof, is adhered to the frame 3 such that there is a gap between the reticle base plate 5 and the pellicle 1. In order to equalise the pressure between the space 9 between the reticle base plate 5 and the pellicle 1, and the surrounding atmosphere, a bore hole 11 with a filter is provided in the frame 3.

Such a pellicle, as shown in FIG. 1, comprises a transparent pellicle member made of a highly light-transmissive material, such as 1 micrometer polyamide. A mask 6 is provided on one side of the reticle base plate 5 (over the reticle) and the reticle is then exposed to light (through the mask 6) to create the required circuit configuration on a silicium wafer.

The resolution of lithography has gradually become higher in recent years, and realise such resolution, light of a shorter wavelength has gradually come to be used as a light source. Specifically, for example, the use of a fluorine excimer laser (157 nm) is becoming increasingly desirable. However, conventional pellicle materials absorb radiation at 157 nm. Thus, the use of glass plates composed of an inorganic compound (such as silicon glass) or the like as the pellicle membrane has been considered.

When these inorganic compounds are used as the pellicle membrane, the membrane should ideally have a certain thickness to give the membrane the required strength and stiffness. However, practically, the plate must be significantly thinner than this certain thickness to avoid distortion of the radiation and such a plate may become curved due to gravity force, which may cause deviation of the light path for light exposure at the pellicle membrane surface, and thus adversely affect the light exposure.

US Patent Application No. US 2001/0004508 describes an arrangement in which the pellicle membrane comprises a thin glass plate adhered to a frame under a photomask such that the membrane tends to warp downwardly due to gravity. However, by decompressing the air in the space between the pellicle and the reticle, the pellicle membrane is lifted, and hence the deformation due to gravity (and its own weight) can be relieved or eliminated.

The applicant's co-pending application (ID699564) describes an arrangement for protecting a reticle used in semiconductor chip fabrication from contamination, the apparatus comprising a pellicle member disposed over the reticle with a gas-tight space therebetween by connection means, characterized in that the connection means is configured to permit movement of the entire pellicle member in a direction substantially perpendicular to the reticle in response to changes in gas pressure difference between said space and the atmosphere.

Thus, in the above-described arrangement, the pellicle membrane is mounted in a flexible way such that the difference in gas pressure inside the reticle and the outside pressure will carry or support the pellicle and results in no deformation of the pellicle itself.

However, for applications where, for optical reasons, the deviations in the vertical position and/or tilt angle of the pellicle should be smaller than can be achieved with the above-described arrangement, we have devised a modified arrangement

Referring to FIG. 2 of the drawings, an arrangement according to an embodiment of the present invention comprises a reticle base plate 5 on one surface of which is provided a reticle (i.e. a photolithographic surface). The reticle base plate 5 is mounted on a frame 3 and a patterned mask 6 is provided on the reticle surface.

A transparent pellicle member 1, comprising an inner or central portion 1A and an outer peripheral portion 1B, is mounted across the reticle, substantially parallel thereto and with a space 9 therebetween. The central portion 1A of the pellicle 1 is fixed with regard to position and tilt angle to the reticle base plate 5 by means of one or more anchors 50. In an alternative embodiment, fixing means may be provided all around the periphery of the central portion of the pellicle 1. In the case of such a “closed construction, one or more bore holes should be provided so as to ensure that there is only one gas pressure in the arrangement. An advantage of selecting a limited number of fixation points (e.g. 4) is that the deformation of the pellicle 1 due to such fixation can be minimised, especially where a statically determined method of fixation is chosen, as shown schematically in FIG. 2.

The outer or peripheral portion 1B of the pellicle 1 is separate from the central portion. It is connected on each side to the central portion 1A and to the frame 3 by means of flexible connectors 30, which are sufficiently flexible to permit movement of the peripheral portion 1B of the pellicle in a direction perpendicular to the reticle, but is sufficiently resistant to movement thereof in other directions. The flexible connection members 20 may be in the form of a “bellows” type arrangement, to provide optimum flexibility in the direction perpendicular to the reticle, but significant resistance in all other directions. In the example illustrated schematically in FIG. 2, the connectors 30 comprise flexible inverted U-shaped members. Many other types of flexible connector will be apparent to a person skilled in the art, and the invention is not intended to be limited in this regard.

As a result, the gas pressure difference between the space 9 and the surrounding atmosphere supports the outer portion 1B of the pellicle 1 (which may comprise, for example, silicon glass) using the weight of that portion of the glass pellicle itself. The vertical position and tilt angle of the inner portion 1A (i.e. the optical part) of the pellicle 1 is fixed, whereas the outer portion 1B is able to move in direction perpendicular to the reticle in response to differences in gas pressure between the space 9 and the atmosphere, i.e. such movement causes a difference in inside and outside air pressure which supports the outer portion 1B (and the inner portion 1A) of the pellicle 1 and to avoid deformation thereof. In other words, the outer portion 1B of the pellicle 1 “floats” on the gas pressure difference, which pressure difference is maintained in a passive way, i.e. no electrical, pneumatic or other external connection is required, and the inner portion 1A of the pellicle membrane 1 is balanced by the outer portion 1B.

In the case where the pellicle is rectangular in shape, it may be difficult to obtain a flexible connection between the pellicle and the support frame. In such a case, a radius may be used at the corners of the pellicle membrane.

It should be noted that the above-mentioned embodiment illustrates rather than limits the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. In a device claim enumerating several means, several of these means may be embodied by one and the same item of hardware. The mere fact that certain measures are recited in mutually different dependent claims does not indicate that a combination of these measures cannot be used to advantage.

1. Apparatus for protecting a reticle used in semiconductor chip fabrication from contamination, the apparatus comprising a pellicle member 1) disposed over said reticle with a space (9) therebetween by connection means (30), characterized in that said pellicle member (1) comprises a central portion (1A) and an outer portion (1B), said central (1A) and outer portions (1B) being separate from each other, said central portion (1A) having a fixed position and tilt angle, in use, and said connection means (30) being configured to permit movement of said outer portion (1B) in a direction substantially perpendicular to said reticle in response to changes in gas pressure difference between said space (9) and the atmosphere.

2. Apparatus according to claim 1, wherein the connection means comprises one or more flexible connection members (30).

3. Apparatus according to claim 2, wherein said connection members are arranged to extend and contract in response to said pressure differences so as to permit movement of the outer portion (1B) of the pellicle member (1) in a direction substantially perpendicular to the reticle.

4. Apparatus according to claim 1, wherein the connection means (30) comprises one or more brackets slidably or otherwise connecting the outer portion (1B) of the pellicle member (1) to a support frame (3), such that it can move in a direction substantially perpendicular to the reticle.

5. Apparatus according to claim 1, further comprising a support frame (3) having longitudinal guides in which the edges of the outer portion (1B) of the pellicle member (1) are arranged to be received in a gas-tight manner, such that it is permitted to move up and down relative to the reticle by sliding up and down the gas-tight guides.

6. Apparatus according to claim 1, wherein the inner portion (1A) of the pellicle member (1) is fixed with regard to its position and tilt angle by means of one or more anchor points (50).

7. Apparatus according to claim 6, wherein said anchor points (50) may extend from selected positions on a reticle base plate (5), on which the reticle is supported or provided.

8. Apparatus according to claim 1, wherein the pellicle member (1) is formed of silicon glass.

9. Apparatus according to claim 1, wherein the reticle is provided on a reticle base plate (5), which base plate (5) is provided with a support frame (3) to which the outer portion (1B) of the pellicle member (1) is connected

10. A method of protecting a reticle used in semiconductor chip fabrication from contamination, the method comprising the steps of providing a pellicle member (1) and disposing it over said reticle with a space (9) therebetween by connection means, characterized in that said pellicle member (1) comprises a central portion (1A) and an outer portion (1B), said central (1A) and outer portions (1B) being separate from each other, said central portion (1A) having a fixed position and tilt angle, in use, and said connection means (30) being configured to permit movement of said outer portion (1B) in a direction substantially perpendicular to said reticle in response to changes in gas pressure difference between said space (9) and the atmosphere.

11. A method of fabricating a semiconductor chip, comprising the steps of providing a reticle and apparatus for protecting said reticle from contamination, according to claim 1, providing a patterned mask (6) on said reticle, and irradiating said reticle through the central portion (1A) of the pellicle member (1) and the mask (6).

12. A semiconductor-chip-fabricated in accordance with the method of claim 11.
